(19) United States
(12) Patent Application Publication
(10) Pub. No.: US 2010/0116546 A1
(43) Pub. Date: May 13, 2010

(54) CASE HAVING SIGNAL TRANSMISSION LINE

(75) Inventor: Hsin-Lung LIN, Hsinchu City (TW)

Correspondence Address: RABIN & Berdo, PC, 1101 14TH STREET, NW, SUITE 500, WASHINGTON, DC, 20005, US

(73) Assignee: Smart Approach CO., LTD., Hsinchu (TW)

(21) Appl. No.: 12/269,209

(22) Filed: Nov. 12, 2008

(51) Int. Cl. H05K 5/00

(52) U.S. Cl. 174/520

(57) ABSTRACT

A case having a signal transmission line includes a case body and a signal transmission line. The case body has a surface with at least one groove disposed thereon. The signal transmission line is positioned within the groove, and has a core for transmitting a signal. The case having a signal transmission line further includes an insulating layer. The insulating layer is located between the groove and the core, so as to insulate the core from the case body. By employing the case body or a conductive layer coated in the groove to serve as a metal ground layer, the external electromagnetic wave interference can be avoided when transmitting a signal via the signal transmission line, and the manufacturing cost of the signal transmission line can be effectively reduced as well.

### BACKGROUND OF THE INVENTION

1. Field of the Invention

The present invention relates to a case, and more particularly to a case having a signal transmission line.

2. Related Art

Wireless communication technology utilizes electromagnetic waves to transmit signals, so that it communicates with a remote device without connecting to a wire in usage. Therefore, the wireless communication technology is quite convenient while a user moves all around. Accordingly, more and more products using wireless communication technology have been proposed currently such as a mobile phone, and a laptop computer. However, since these products utilize electromagnetic waves to transmit signals, an antenna used to receive and transmit electromagnetic wave signals becomes an indispensable element. Nowadays, the antenna is mainly classified into an antenna disposed at an exterior of the device, and an antenna built in the device. However, the antenna disposed at an exterior of the device not only influences the size and appearance of the product, but also has defects of being easily crashed by an external force, easily flexed and broken up, so the built-in antenna has already become a tendency of a mainstream.

When being configured within a device, the built-in antenna device is electrically connected to a microprocessor in the device via a signal transmission line. The message to be transmitted is encoded into a signal by the microprocessor, and then the signal is transmitted via the signal transmission line. The above signal is directly fed into a signal feed-in portion of the built-in antenna device via the signal transmission line, and then transmitted to a radiation portion thereof by circuits or metal structures in the built-in antenna device.

However, since the current device tends to be much lighter and thinner, when a signal transmission line is disposed in a device for electrically connecting a built-in antenna device to a microprocessor, it is rather difficult to implement the wiring within the device due to the volume of the signal transmission line. Meanwhile, when a signal is transmitted via the signal transmission line, the external electromagnetic wave interference can be avoided and the superior signal quality can be achieved. However, the manufacturing cost is generally quite high due to a high cost of the signal transmission line.

### SUMMARY OF THE INVENTION

Accordingly, in view of the above problems, the present invention is directed to a case having a signal transmission line, which is adapted to overcome the difficulty in wiring caused by a volume of a signal transmission line, and solve the problem of a high manufacturing cost.

A case having a signal transmission line is provided in the present invention, which includes a case body and a signal transmission line.

The case body has a surface with at least one groove disposed thereon. The signal transmission line is positioned within the groove, and has a core for transmitting a signal.

The case having a signal transmission line further includes an insulating layer and a conductive layer. The insulating layer is located between the groove and the core, so as to insulate the core from the case body. The insulating layer surely wraps the core and insulates the core from the exterior. The conductive layer is located between the groove and the insulating layer, so as to protect a signal transmitted via the core from being interfered by external electromagnetic waves.

In the case having a signal transmission line according to the present invention, at least one groove is disposed on the case body and a signal transmission line having a core is disposed within the groove. Meanwhile, the core is insulated from the exterior by means of being wrapped by an insulating layer, or disposing the insulating layer between the groove and the core, and is used to transmit a signal. By employing a case body made of a metal or a conductive layer disposed within the groove of the case body to serve as a ground layer of the signal transmission line, the influences on the signal transmission of the inner core caused by the external electromagnetic waves can be avoided. On one hand, the case having a signal transmission line can overcome the wiring difficulty of the signal transmission line; on the other hand, the manufacturing cost of the external ground layer of the signal transmission line can be reduced, thereby lowering the overall cost.

### BRIEF DESCRIPTION OF THE DRAWINGS

The present invention will become more fully understood from the detailed description given herein below for illustration only, and thus is not limitative of the present invention, and wherein:

FIG. 1 is a schematic view of a first embodiment of the present invention;

FIG. 2 is a schematic view of a second embodiment of the present invention; and

FIG. 3 is a schematic view of a third embodiment of the present invention.

### DETAILED DESCRIPTION OF THE INVENTION

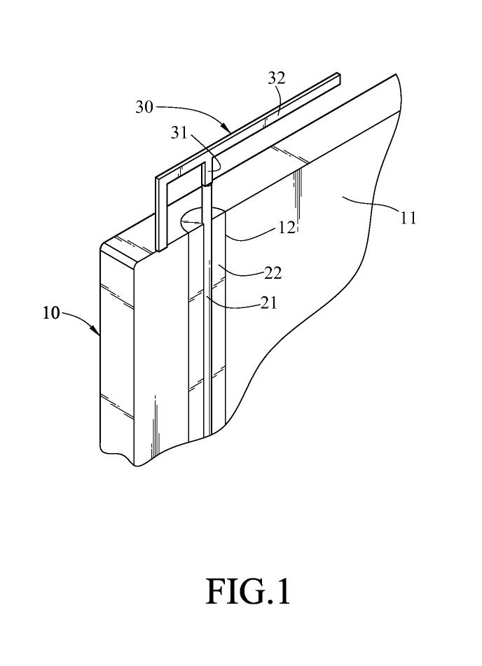

FIG. 1 is a schematic view of a first embodiment of the present invention. In this embodiment, a case having a signal transmission line includes a case body 10 and a signal transmission line, and an antenna 30.

The case body 10 has a surface 11 with a groove 12 disposed thereon.

The signal transmission line is positioned within the groove 12, and includes a core 21. The core 21 is a conductor used for transmitting a signal.

The case having a signal transmission line further includes an insulating layer 22. The insulating layer 22 is located between the groove 12 and the core 21, so as to insulate the core 21 from the case body 10. In this embodiment, the insulating layer 22 is located on the surface of the groove 12, and isolates the core 21 from the case body 10 made of a metal.

The antenna 30 has a signal feed-in portion 31 and a radiation portion 32. The signal feed-in portion 31 is connected to the core 21. The core 21 is used to feed a signal into the radiation portion 32 via the signal feed-in portion 31, and the signal is received and transmitted via the radiation portion 32. The antenna 30 is electrically connected to the case body 10 made of a metal, and uses the case body 10 made of a metal to act as a ground layer.

The groove 12 may be formed on the surface 11 of the case body 10 by means of pressing. The case body 10 may be made of a metal, for example, aluminum, aluminum magnesium alloy, and plastic steel.

The core 21 may be made of a metal with desirable conductivity such as copper or silver.

The insulating layer 22 may be made of a material with desirable insulation feature such as dielectric, for example, air or foam.

The antenna 30 may be an antenna printed on a substrate, or an antenna made of a metal.

In this embodiment, when an external signal is transmitted to the antenna 30 via the signal transmission line, the signal is firstly fed in through the signal feed-in portion 31 of the antenna 30, and then transmitted to the radiation portion 32 of the antenna 30 and radiated by the radiation portion 32. When being transmitted within the signal transmission line, the signal is transmitted by the core 21, and the core 21 is isolated from the case body 10 made of a metal by the insulating layer 22. The groove 12 is disposed on the surface 11 of the case body 10 to accommodate the signal transmission line, which is not only convenient for wiring, but also saves the cost, since the case body 10 made of a metal in this embodiment further serves as the ground layer of the signal transmission line to omit an external mesh-shaped metal structure during the manufacturing of the signal transmission line.

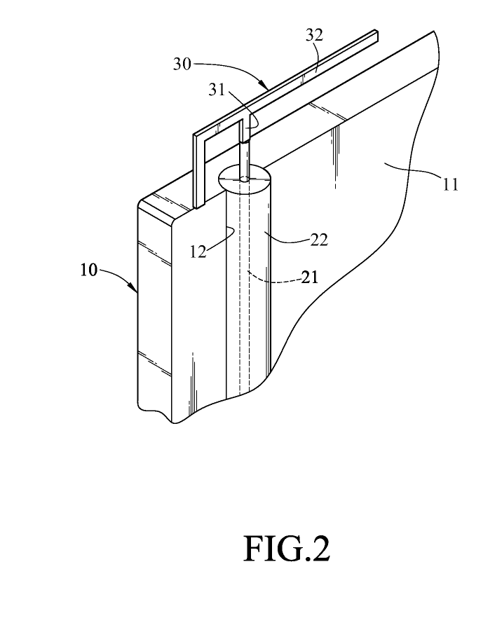

FIG. 2 is a schematic view of a second embodiment of the present invention. The structure design in this embodiment is substantially similar to that in the above embodiment, but differs in that, the insulating layer 22 wraps the core 21 and insulates the core 21 from the exterior. In this way, the core is prevented from contacting other elements on the other side of the case body 10 to result in the loss of signal.

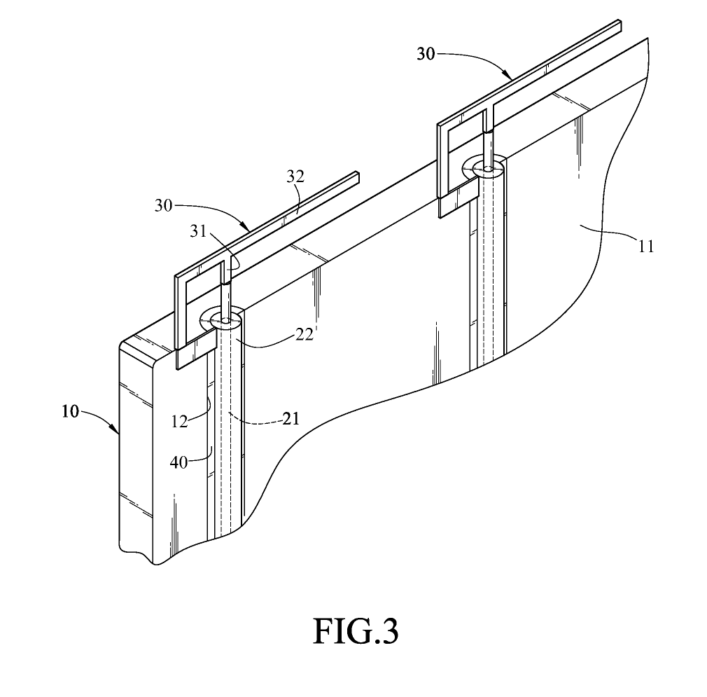

FIG. 3 is a schematic view of a third embodiment of the present invention. The structure design in this embodiment is substantially similar to that in the second embodiment, but differs in that the case body 10 in this embodiment may be made of other nonmetallic materials such as plastic and carbon fiber.

However, since the case body 10 may be made of a nonmetallic material, or a metal material with a poor conductivity, it cannot be used as a ground layer to ground the signal, and cannot protect the signal transmitted via the core from being interfered by external electromagnetic waves either.

Therefore, a conductive layer 40 is further included in this embodiment. The conductive layer 40 is located between the groove 12 and the insulating layer 22, so as to protect the signal transmitted via the core 21 from being interfered by external electromagnetic waves. The conductive layer 40 may be formed on the surface of the groove 12 through a semiconductor process or print coating, after the groove 12 is disposed on the surface 11 of the case body 10.

The conductive layer 40 may be made of a metal such as gold, silver, or copper, or made of a complex material such as conductive paint.

The groove 12 on the surface 11 of the case body 10 can be disposed integrally while the case body 10 is manufactured, for example, through die casting molding or injection molding. Definitely, the groove 12 may be alternatively excavated on the surface 11 of the case body 10 through a mechanical machining process after the case body 10 has been manufactured.

In this embodiment, when an external signal is transmitted to the antenna 30 via the signal transmission line, the signal is firstly fed in through the signal feed-in portion 31 of the antenna 30, and then transmitted to the radiation portion 32 of the antenna 30 and radiated by the radiation portion 32. When being transmitted within the signal transmission line, the signal is transmitted via the core 21, and the core 21 is isolated from the exterior by the insulating layer 22. The groove 12 is disposed on the surface 11 of the case body 10 to accommodate the signal transmission line. Meanwhile, a conductive layer 40 is formed on the groove 12, which not only serves as a ground layer to ground the signal, but also protects the signal transmitted via the core 21 from being interfered by external electromagnetic waves, so as to omit the external mesh-shaped metal structure during the manufacturing of the signal transmission line, thereby saving the cost.

What is claimed is:

1. A case having a signal transmission line, comprising:
a case body, having a surface with at least one groove disposed thereon; and
a signal transmission line, positioned within the groove, and having a core for transmitting a signal.

2. The case having a signal transmission line according to claim 1, wherein the case body is made of a metal.

3. The case having a signal transmission line according to claim 1, wherein the case body is made of a plastic or a nonconductive material.

4. The case having a signal transmission line according to claim 1, further comprising an insulating layer located between the groove and the core, so as to insulate the core from the case body.

5. The case having a signal transmission line according to claim 4, wherein the insulating layer wraps the core.

6. The case having a signal transmission line according to claim 4, wherein the insulating layer is located on the surface of the groove.

7. The case having a signal transmission line according to claim 4, further comprising a conductive layer located between the groove and the insulating layer, so as to protect a signal transmitted via the core from being interfered by external electromagnetic waves.

8. The case having a signal transmission line according to claim 7, wherein the conductive layer is coated on the surface of the groove.
